(19) United States
(12) Patent Application Publication
(10) Pub. No.: US 2003/0234665 A1
(43) Pub. Date: Dec. 25, 2003

(54) Anti-fuse sense amplifier

(76) Inventors: Sterling Smith, Hsinchu (TW); Henry Tin-Hang Yung, Hsinchu (TW)

Correspondence Address: SHAW PITTMAN, IP GROUP, 1650 TYSONS BOULEVARD, SUITE 1300, MCLEAN, VA, 22102, US

(21) Appl. No.: 10/262,872

(22) Filed: Oct. 3, 2002

Related U.S. Application Data
(60) Provisional application No. 60/389,893, filed on Jun. 20, 2002.

(51) Int. Cl. H03K 19/173

(52) U.S. Cl. 326/37

(57) ABSTRACT

An anti-fuse sensing circuit provided with no static current flowing in an anti-fuse sensing cell thereof. The sensing circuit comprises a switch and an inverter. The switch is operatively connected with an anti-fuse in series between a first power rail and a second power rail thereby forming a sensing node therebetween. The inverter is configured with an input operatively connected to the sensing node and an output operatively connected to the switch. Accordingly, the switch and the inverter constitute a feedback loop so as to sense that the anti-fuse is either un-programmed or programmed.

### CROSS-REFERENCE TO RELATED APPLICATION

The present application claims the priority benefits of U.S. provisional application entitled “STATIC CMOS ANTI-FUSE SENSE AMPLIFIER” filed on Jun. 20, 2002 U.S. Ser. No. 60/389,893. All disclosures of this application are incorporated herein by reference.

### BACKGROUND OF THE INVENTION

1. Field of the Invention

The present invention generally relates to a sensing circuit for a submicron anti-fuse technology. More particular, the present invention relates to a sense amplifier provided with no static current flowing in an anti-fuse sensing cell thereof.

2. Description of Related Arts

Anti-fuses are used extensively on integrated circuits to provide various circuit trimming functions. Specifically, analog type components such as comparators, amplifiers, etc. made in MOS technology may require some parameter adjustments, and the anti-fuses may be used extensively in order to provide a selective trimming of the parameter values.

The anti-fuse device is blown by applying a higher than normal voltage or applying laser to the anti-fuse, which produces a short circuit where an open circuit once existed. The blown anti-fuse facilitates a current path whose change of state from non-conducting to conducting represents a change in a logic state. The anti-fuse device generally comprises two conductors, either metal and/or a semiconductor material having some kind of dielectric or insulating material between the two conductors. In the recent past this dielectric was set to approximately half the normal thickness of a FET thin oxide gate, so that in the presence of a high voltage or laser power, it was electrically broken down to change from the non-conducting state to the conducting state, while not affecting in any permanent way the remaining components of the circuit.

For sensing the logic state of the anti-fuse device, a sense amplifier is provided to identify the anti-fuse device to be either non-conducting or conducting. However, the sense amplifier should require very low power consumption in the application of complex communications integrated circuits.

### SUMMARY OF THE INVENTION

Therefore, it is an object of the present invention to provide a sense amplifier having no static current flowing therethrough.

To attain this object, the present invention provides a sensing circuit for an anti-fuse device. The sensing circuit comprises a switch and an inverter. The switch is operatively connected with the anti-fuse device in series between a first power rail and a second power rail thereby forming a sensing node therebetween. The inverter is configured with an input operatively connected to the sensing node and an output operatively connected to the switch. Accordingly, the switch and the inverter constitute a feedback loop so as to sense that the anti-fuse device is either un-programmed or programmed.

Moreover, the present invention provides a sensing circuit comprising a switch, an inverter and a buffer. The switch is operatively connected with the anti-fuse device in series between a first power rail and a second power rail thereby forming sensing node therebetween. The inverter is configured with an input operatively connected to the sensing node and an output operatively connected to the switch. The buffer is operatively connected to the output of the inverter. Accordingly, the switch and the inverter constitute a feedback loop so as to sense that the anti-fuse device is either un-programmed or programmed.

Furthermore, the present invention provides a sensing circuit for an anti-fuse by including an NMOS switch transistor and a CMOS inverter. The NMOS switch transistor is operatively connected with the anti-fuse in series between a first power rail and a second power rail thereby forming a sensing node therebetween. The CMOS inverter is configured with an input operatively connected to the sensing node and an output operatively connected to a gate of the NMOS switch transistor. Alternatively, the present invention can provide a sensing circuit for an anti-fuse by including a PMOS switch transistor and a CMOS inverter. The PMOS switch transistor is operatively connected with the anti-fuse in series between a first power rail and a second power rail thereby forming a sensing node therebetween. The CMOS inverter is configured with an input operatively connected to the sensing node and an output operatively connected to a gate of the PMOS switch transistor.

Accordingly, the sensing circuits according to the present invention have no static current flowing in the anti-fuse sensing cell thereof.

### BRIEF DESCRIPTION OF THE DRAWINGS

FIG. 1 depicts a schematic circuit diagram of a sense amplifier used for sensing the state of an anti-fuse device in accordance with one preferred embodiment of the present invention;

FIG. 2 depicts a detailed circuit diagram of FIG. 1;

FIG. 3 depicts a schematic circuit diagram of a sense amplifier used for sensing the state of an anti-fuse device in accordance with another preferred embodiment of the present invention; and

FIG. 4 depicts a detailed circuit diagram of FIG. 3.

### DETAILED DESCRIPTION OF THE PREFERRED EMBODIMENTS

The present invention relates to a sensing circuit for a new submicron anti-fuse technology. The anti-fuse technology has the favorable properties of extremely high impedance when un-programmed, and very low impedance when programmed. It is noted that the high impedance approximates the impedance of inter/intra metal dielectric and the low impedance approximates that of a via through the metal dielectric. The present application is used in the application of very low power consumption, especially for complex communication integrated circuits.

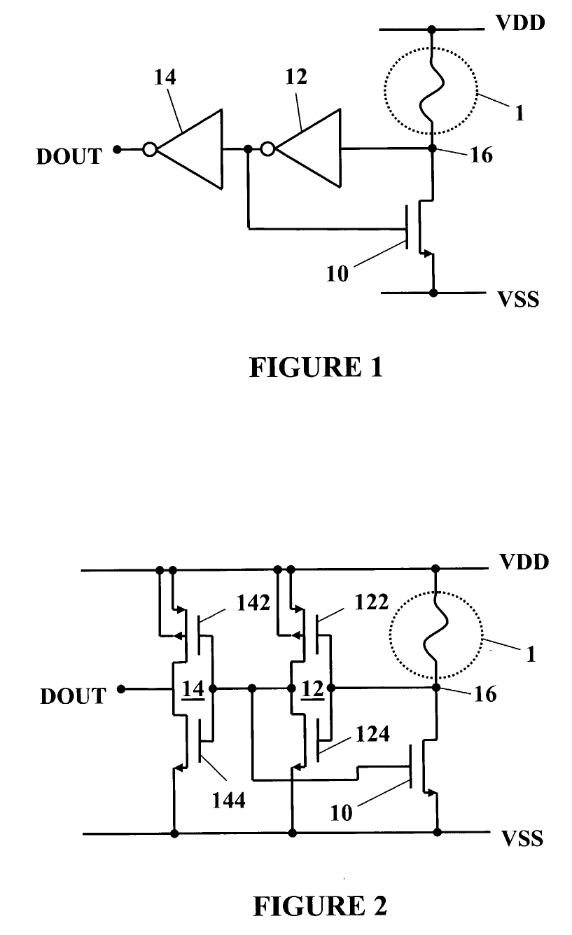

Referring to FIG. 1, a circuit diagram of a sense amplifier used for an anti-fuse device 1 in accordance with one preferred embodiment of the present invention is schematically depicted. In FIG. 1, the anti-fuse sense amplifier of the present invention is provided with a switch 10, an inverter 12 and a buffer 14. The switch 10 is electrically connected with the anti-fuse device 1 in series between a VDD power rail and a VSS power rail. For example, VSS can be ground and VDD can be 5V, 3.3V, 2.5V or the less. The connection of the switch 10 and the anti-fuse device 1 forms a sensing node 16. In this embodiment, the anti-fuse device 1 is connected between the VDD power rail and the sensing node 16 whereas the switch 10 is connected between the sensing node 16 and the VSS power rail.

The inverter 12 is configured with an input connected to the sensing node 16 and an output connected to control the ON/OFF operation of the switch 10, Accordingly, the switch 10 and the inverter 12 constitute a feedback loop so as to sense whether the sensing node 16 is near VSS or VDD. The buffer 14 inverts the voltage at the output of the inverter 12 to drive the output node DOUT, accordingly. The primary purpose of the buffer 14 is to buffer the output of the inverter 12 and the sensing node 16 from external influence and drive the output load (not shown in the drawing).

Referring to FIG. 2, a detailed circuit diagram of FIG. 1 is schematically depicted as an example. As shown in FIG. 2, the switch 10 is implemented by an NMOS transistor provided with its drain and source connected to the sensing node 16 and the VSS power rail, respectively. The inverter 12 is implemented by including a PMOS transistor 122 and an NMOS transistor 124, where the buffer 14 is implemented by including a PMOS transistor 142 and an NMOS transistor 144. The PMOS transistor 122 is configured with its source and gate connected to the VDD power rail and sensing node 16, respectively. The NMOS 124 is configured with its source and gate connected to the VSS power rail and the sensing node 16, respectively. The drains of the PMOS transistor 122 and the NMOS transistor 124 are both tied to the gate of the NMOS transistor 10. Moreover, the PMOS transistor 142 is configured with its source and gate connected to the VDD power rail and the gate of the NMOS transistor 10, respectively. The NMOS 144 is configured with its source and gate connected to the VSS power rail and the gate of the NMOS transistor 10, respectively. In addition, the drains of the PMOS transistor 142 and the NMOS transistor 144 are tied together to form the output node DOUT.

As mentioned above, the inverter 12 is utilized to sense whether the sensing node 16 is near VDD or VSS. If the sensing node 16 is near VSS, the inverter 12 will output a HIGH voltage at the output of the inverter 12. The buffer 14 inverts the voltage at the output of the inverter 12 so as to drive the output node DOUT to a LOW voltage, accordingly. The output of the inverter 12 is connected to the gate of the NMOS transistor 10 such that the HIGH voltage at the output of the inverter 12 will turn on the NMOS transistor 10 which will allow any excess charge on the sensing node 16 to be discharged to the VSS power rail. Thus, this feedback mechanism will drive the sensing node 16 to VSS when the anti-fuse device 1 is un-programmed. When the anti-fuse device 1 is programmed, the sensing node 16 is coupled to VDD with low-impedance causing the output of the inverter 12 to be driven LOW by the inverter 12 which in turn turns the NMOS transistor 10 off to prevent any DC current from flowing through the anti-fuse device 1 and the NMOS transistor 10 as well. In both cases of programmed and un-programmed anti-fuse devices, the sensing node 16 is driven to HIGH or LOW, respectively, and not allowed to float such that the possibility of erroneous detection can be eliminated. Accordingly, the output node DOUT of the anti-fuse sense amplifier outputs a HIGH or “1” when the anti-fuse device 1 is programmed (shorted), and a LOW or “0” when the anti-fuse device 1 is un-programmed (open).

By assuming that the node 16 is initially at a false-HIGH state while the anti-fuse device 1 is un-programmed, the output of the inverter 12 is driven LOW to turn the NMOS transistor 10 off and thus the sensing node 16 seems to be temporarily floating at an erroneous output. However, the leakage current at the drain junction can discharge the sensing node 16 to VSS so as to turn on the NMOS transistor 10 and generate correct digital output. To the contrary, by assuming that the node 16 is initially at a false-LOW state while the anti-fuse device 1 is programmed, the output of inverter 12 is driven HIGH to turn on the NMOS transistor 10 and thus the sensing node 16 is temporarily held at erroneous-LOW output. However, the near-short path between the sensing node 16 and VDD provides appropriate charge to drive the sensing node to VDD so as to turn off the NMOS transistor 10 and thus generate correct digital output. As a result, no false sensing or floating node may occur to cause static current whether the anti-fuse device 1 is un-programmed or programmed. Therefore, the present invention uses no DC power except CMOS technology limited leakage currents. It also requires no read-cycle, as it continuously outputs the correct digital output.

Accordingly, the advantages of the anti-fuse sense amplifier in accordance with the one preferred embodiment of the present invention are summarized as follows:

(1) The sensing node 16 has no path to VDD when anti-fuse is un-programmed;

(2) Tiny leakage current from the drain of the NMOS transistor 10 discharges the sensing node 16 to VSS when anti-fuse is un-programmed, and the inverter 12 has not yet turned the NMOS transistor 10 on;

(3) The feedback connection of the NMOS transistor 10 and the inverter 12 is utilized to help maintain the sensing node 16 at the correct voltage;

(4) No static current flows in the anti-fuse sensing cell;

(5) Sensing cell needs no read-cycle and the output DOUT is driven to correct value immediately when power is applied; and

(6) Very low startup current can be achieved as well.

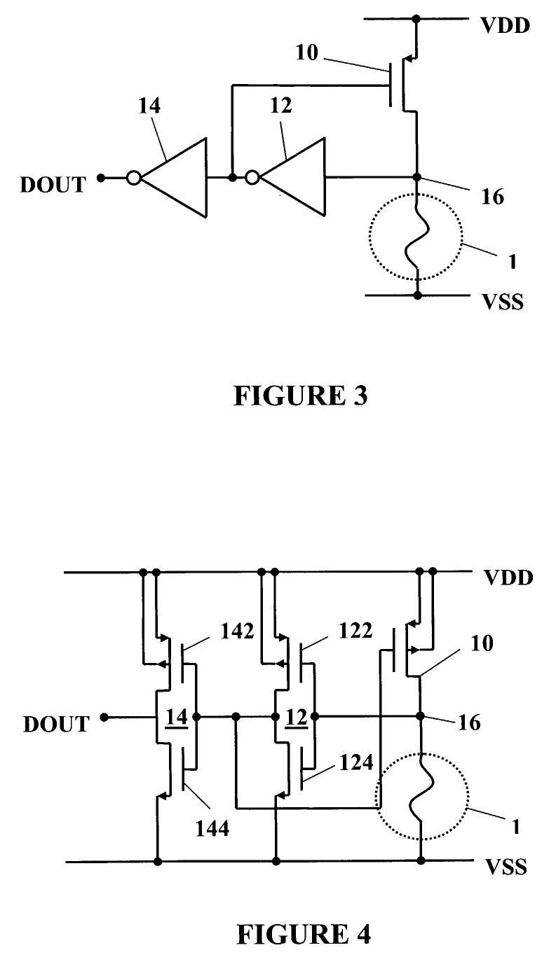

Referring to FIG. 3, a circuit diagram of a sense amplifier used for an anti-fuse device 1 in accordance with another preferred embodiment of the present invention is schematically depicted. In FIG. 3, the anti-fuse sense amplifier of the present invention is provided with a switch 10, an inverter 12 and a buffer 14. The switch 10 is electrically connected with the anti-fuse device 1 in series between a VDD power rail and a VSS power rail. For example, VSS can be ground and VDD can be 5V, 3.3V, 2.5V or the less. The connection of the switch 10 and the anti-fuse device 1 forms a sensing node 16. In this embodiment, the anti-fuse device 1 is connected between the VSS power rail and the sensing node 16 whereas the switch 10 is connected between the sensing node 16 and the VDD power rail.

The inverter 12 is configured with an input connected to the sensing node 16 and an output connected to control the ON/OFF operation of the switch 10, Accordingly, the switch 10 and the inverter 12 constitute a feedback loop so as to sense whether the sensing node 16 is near VSS or VDD. The buffer 14 inverts the voltage at the output of the inverter 12 to drive the output node DOUT, accordingly. The primary purpose of the buffer 14 is to buffer the output of the inverter 12 and the sensing node 16 from external influence and drive the output load (not shown in the drawing).

Referring to FIG. 4, a detailed circuit diagram of FIG. 3 is schematically depicted as an example. As shown in FIG. 4, the switch 10 is implemented by a PMOS transistor provided with its drain and source connected to the sensing node 16 and the VDD power rail, respectively. The inverter 12 is implemented by including a PMOS transistor 122 and an NMOS transistor 124, where the buffer 14 is implemented by including a PMOS transistor 142 and an NMOS transistor 144. The PMOS transistor 122 is configured with its source and gate connected to the VDD power rail and sensing node 16, respectively. The NMOS 124 is configured with its source and gate connected to the VSS power rail and the sensing node 16, respectively. The drains of the PMOS transistor 122 and the NMOS transistor 124 are both tied to the gate of the PMOS transistor 10. Moreover, the PMOS transistor 142 is configured with its source and gate connected to the VDD power rail and the gate of the PMOS transistor 10, respectively. The NMOS 144 is configured with its source and gate connected to the VSS power rail and the gate of the PMOS transistor 10, respectively. In addition, the drains of the PMOS transistor 142 and the NMOS transistor 144 are tied together to form the output node DOUT.

As mentioned above, the inverter 12 is utilized to sense whether the sensing node 16 is near VDD or VSS. If the sensing node 16 is near VDD, the inverter 12 will output a LOW voltage at the output of the inverter 12. The buffer 14 inverts the voltage at the output of the inverter 12 so as to drive the output node DOUT to a HIGH voltage, accordingly. The output of the inverter 12 is connected to the gate of the PMOS transistor 10 such that the LOW voltage at the output of the inverter 12 will turn on the PMOS transistor 10 which will allow the sensing node 16 to be charged to the VDD. This feedback mechanism will drive the sensing node 16 to VDD when the anti-fuse device 1 is un-programmed. When the anti-fuse device 1 is programmed, the sensing node 16 is coupled to VSS with low-impedance causing the output of the inverter 12 to be driven HIGH by the inverter INV1 which in turn turns the PMOS transistor 10 off to prevent any DC current from flowing through the anti-fuse device 1 and the PMOS transistor 10 as well. In both cases of programmed and un-programmed anti-fuse devices, the sensing node 16 is driven to LOW or HIGH, respectively, and not allowed to float such that the possibility of erroneous detection can be eliminated. Thus, the output node DOUT of the anti-fuse sense amplifier outputs a LOW or “0” when the anti-fuse device 1 is programmed (shorted), and a HIGH or “1” when the anti-fuse device 1 is un-programmed (open).

By assuming that the node 16 is initially at a false-LOW state while the anti-fuse device 1 is un-programmed, the output of the inverter 12 is driven HIGH to turn the PMOS transistor 10 off and thus the sensing node 16 seems to be temporarily floating at an erroneous output. However, the leakage current at the drain junction can charge the sensing node 16 to VDD so as to turn on the PMOS transistor 10 and generate correct digital output. To the contrary, by assuming that the node 16 is initially at a false-HIGH state while the anti-fuse device 1 is programmed, the output of inverter 12 is driven LOW to turn on the PMOS transistor 10 and thus the sensing node 16 is temporarily held at erroneous-HIGH output. However, the near-short path between the sensing node 16 and VSS discharges the sensing node to VSS so as to turn off the PMOS transistor 10 and thus generate correct digital output. As a result, no false sensing or floating node may occur to cause static current whether the anti-fuse device 1 is un-programmed or programmed. Therefore, the present invention uses no DC power except CMOS technology limited leakage currents. It also requires no read-cycle, as it continuously outputs the correct digital output.

Accordingly, the advantages of the anti-fuse sense amplifier in accordance with the another preferred embodiment of the present invention are summarized as follows:

(1) The sensing node 16 has no path to VSS when anti-fuse is un-programmed;

(2) Tiny leakage current from the drain of the PMOS transistor 10 charges the sensing node 16 to VDD when anti-fuse is un-programmed, and the inverter 12 has not yet turned the PMOS transistor 10 on;

(3) The feedback connection of the PMOS transistor 10 and the inverter 12 is utilized to help maintain the sensing node 16 at the correct voltage;

(4) No static current flows in the anti-fuse sensing cell;

(5) Sensing cell needs no read-cycle and the output DOUT is driven to correct value immediately when power is applied; and

(6) Very low startup current can be achieved as well.

Although the description above contains much specificity, it should not be construed as limiting the scope of the invention but as merely providing illustrations of some of the presently preferred embodiments of the present invention. Thus, the scope of the present invention should be determined by the appended claims and their equivalents, rather than by the examples given.

What is claimed is:

1. A sensing circuit for an anti-fuse, comprising:
a switch operatively connected with said anti-fuse in series between a first power rail and a second power rail thereby forming a sensing node therebetween; and
an inverter having an input operatively connected to said sensing node and an output operatively connected to said switch;
wherein said switch and said inverter constitute a feedback loop so as to sense that said anti-fuse is either un-programmed or programmed.

2. The sensing circuit as claimed in claim 1, further comprising a buffer operatively connected to the output of said inverter.

3. The sensing circuit as claimed in claim 2, wherein said buffer is a CMOS buffer.

4. The sensing circuit as claimed in claim 1, wherein said switch comprises an NMOS transistor having a drain connected to said sensing node, a source connected to said second power rail and a gate connected to the output of said inverter.

5. The sensing circuit as claimed in claim 1, wherein said switch comprises an PMOS transistor having a drain connected to said sensing node a source connected to said first power rail and a gate connected to the output of said inverter.

6. The sensing circuit as claimed in claim 1, wherein said inverter is a CMOS inverter.

7. A sensing circuit for an anti-fuse, comprising:
an NMOS switch transistor operatively connected with said anti-fuse in series between a first power rail and a second power rail thereby forming a sensing node therebetween; and
a CMOS inverter having an input operatively connected to said sensing node and an output operatively connected to a gate of said NMOS switch transistor.

8. The sensing circuit as claimed in claim 7, wherein said NMOS switch transistor has a drain operatively connected to said sensing node and a source operatively connected to said second power rail.

9. The sensing circuit as claimed in claim 7, wherein said CMOS inverter comprises:
a PMOS transistor having a source operatively connected to said first power rail and a gate operatively connected to said sensing node; and
an NMOS transistor having a source operatively connected to said second power rail and a gate operatively connected to said sensing node;
wherein drains of said PMOS transistor and said NMOS transistor are operatively connected to the gate of said NMOS switch transistor.

10. The sensing circuit as claimed in claim 7, further comprising a CMOS buffer operatively connected to the output of said CMOS inverter.

11. The sensing circuit as claimed in claim 10, wherein said buffer comprises:
a PMOS transistor having a source operatively connected to said first power rail and a gate operatively connected to the output of said inverter; and
an NMOS transistor having a source operatively connected to said second power rail and a gate operatively connected to the output of said inverter;
wherein drains of said PMOS transistor and said NMOS transistor are tied to form an output node.

12. A sensing circuit for an anti-fuse, comprising:
a PMOS switch transistor operatively connected with said anti-fuse in series between a first power rail and a second power rail thereby forming a sensing node therebetween; and
a CMOS inverter having an input operatively connected to said sensing node and an output operatively connected to a gate of said PMOS switch transistor.

13. The sensing circuit as claimed in claim 12, wherein said PMOS switch transistor has a drain operatively connected to said sensing node and a source operatively connected to said first power rail.

14. The sensing circuit as claimed in claim 12, wherein said CMOS inverter comprises:
a PMOS transistor having a source operatively connected to said first power rail and a gate operatively connected to said sensing node; and
an NMOS transistor having a source operatively connected to said second power rail and a gate operatively connected to said sensing node;
wherein drains of said PMOS transistor and said NMOS transistor are operatively connected to the gate of said PMOS switch transistor.

15. The sensing circuit as claimed in claim 12, further comprising a CMOS buffer operatively connected to the output of said CMOS inverter.

16. The sensing circuit as claimed in claim 15, wherein said buffer comprises:
a PMOS transistor having a source operatively connected to said first power rail and a gate operatively connected to the output of said inverter; and
an NMOS transistor having a source operatively connected to said second power rail and a gate operatively connected to the output of said inverter;
wherein drains of said PMOS transistor and said NMOS transistor are tied to form an output node.
